(19) United States
(12) Patent Application Publication
(10) Pub. No.: US 2024/0291485 A1
(43) Pub. Date: Aug. 29, 2024

(54) POWER SWITCH WITH SOFT DIODE CONNECTION

(71) Applicant: TEXAS INSTRUMENTS INCORPORATED, Dallas, TX (US)

(72) Inventors: Huijuan LI, Plano, TX (US); Xiaochun ZHAO, Allen, TX (US); Tianhong YANG, Dallas, TX (US)

(21) Appl. No.: 18/173,156

(22) Filed: Feb. 23, 2023

(51) Int. Cl. H03K 17/687; H03K 5/24

(52) U.S. Cl. CPC H03K 17/6872; H03K 5/24; H02M 3/07; H03K 2217/0063

(57) ABSTRACT

A circuit includes a first transistor, a second transistor, and a resistor. The first transistor is coupled between a switch voltage input and a switch voltage output. The first transistor has a first control terminal. The second transistor is coupled between the switch voltage input and the first control terminal. The second transistor has a second control terminal coupled to a low-power mode terminal. The resistor is coupled in series with the second transistor between the first control terminal and the switch voltage input.

### BACKGROUND

A high-side switch is a switch that is connected between a power supply and a load circuit to control provision of power to the load circuit. The switching device in a high-side switch circuit may be a relay or a semiconductor switching device, such as a transistor. Semiconductors provide a number of advantages over electro-mechanical switches in high-side switching applications. For example, semiconductor switches may reduce the risk of electric spark, reduce circuit area, and reduce cost relative to electro-mechanical switches.

### SUMMARY

In one example, a circuit includes a first transistor, a second transistor, and a resistor. The first transistor is coupled between a switch voltage input and a switch voltage output. The first transistor has a first control terminal. The second transistor is coupled between the switch voltage input and the first control terminal. The second transistor has a second control terminal coupled to a low-power mode terminal. The resistor is coupled in series with the second transistor between the first control terminal and the switch voltage input.

In another example, a circuit includes a first transistor, a second transistor, and a resistor. The first transistor has a first current terminal, a second current terminal, and a control terminal. The first current terminal is coupled to a switch voltage input. The second current terminal is coupled to a switch voltage output. The first transistor is configured to operate as a diode based on a low-power mode signal. The second transistor is coupled between the first current terminal and the control terminal. The second transistor is configured to diode-connect the first transistor based on a low-power mode signal. The resistor is coupled in series with the second transistor between the control terminal and the first current terminal. The resistor is configured to limit current flow from the switch voltage input to the control terminal.

In a further example, a circuit includes a power source, a load circuit, a controller, and a high-side switch circuit. The power source has a power source voltage output. The load circuit has a load voltage input. The controller has a switch enable output. The high-side switch circuit has a switch voltage input, a switch voltage output, and a switch control input. The switch voltage input is coupled to the power source voltage output. The switch voltage output is coupled to the load voltage input. The switch control input is coupled to the switch enable output. The high-side switch circuit includes a first transistor, a second transistor, and a resistor. The first transistor has a first current terminal, a second current terminal, and a control terminal. The first current terminal is coupled to the switch voltage input. The second current terminal is coupled to the switch voltage output. The first transistor is configured to operate as a diode based on a low-power mode signal. The second transistor is coupled between the first current terminal and the control terminal. The second transistor is configured to diode-connect the first transistor based on the low-power mode signal. The resistor is coupled between the second transistor and the switch voltage input. The resistor is configured to limit current flow from the switch voltage input to the control terminal.

### BRIEF DESCRIPTION OF THE DRAWINGS

FIG. 1 is a block diagram of an example high-side switch circuit.

FIG. 2 is a schematic level diagram of an example high-side switch circuit that includes “soft diode” operation to protect the switching transistor.

FIG. 3 is a graph of example signals in the high-side switching circuit of FIG. 2 with slowly increasing load current.

FIG. 4 is a graph of example signals in the high-side switching circuit of FIG. 2 with quickly increasing load current.

FIG. 5 is a block diagram of an example system that includes the high-side switch of FIG. 1 or FIG. 2.

### DETAILED DESCRIPTION

Some high-side switch applications can benefit from a high-side switch circuit that can operate in a low-power mode when load current is small. For example, a high-side switch circuit may consume less than 10 microamperes when operating in the low-power mode. The high-side switch circuit monitors the current provided to the load and reverts to a normal operating mode when the load current exceeds a predetermined threshold (e.g., 200 milliamperes). If load current increases due to a fault (e.g., a short circuit or other condition causing a rapid increase in load current), then the main switching transistor of the high-side switching circuit should be turned off quickly to avoid damage.

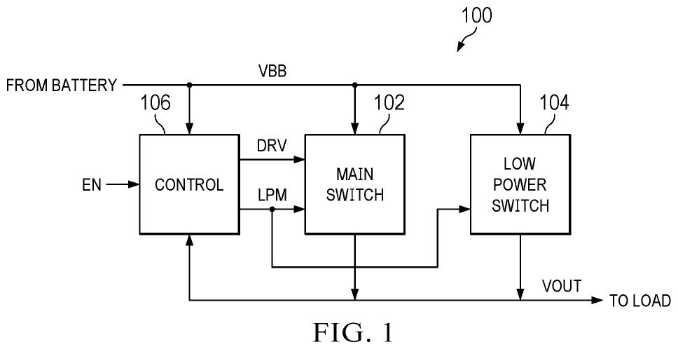

FIG. 1 is a block diagram of an example high-side switch circuit 100. The high-side switch circuit 100 includes a main switch 102, a low-power switch 104, and a control circuit 106. The main switch 102 is a power switch and includes an input power terminal and an output power terminal. The low-power switch 104 is coupled in parallel with the main switch 102 and also includes an input power terminal and an output power terminal. The input power terminals of the main switch 102 and the low-power switch 104 are coupled to a power source, such as a battery. The output power terminals of the main switch 102 and the low-power switch 104 are coupled to a load circuit.

The control circuit 106 controls the operation of the main switch 102 and the low-power switch 104. The control circuit 106 includes a low-power mode output coupled to a low-power mode input of the main switch 102 and a low-power mode input of the low-power switch 104. The control circuit 106 provides a low-power mode signal (LPM) at the low-power mode output for controlling the main switch 102 and the low-power switch 104. The control circuit 106 also include a drive output coupled to a drive input of the main switch 102. The control circuit 106 provides a drive signal (DRV) at the drive output for controlling the main switch 102. The control circuit 106 may include an enable input for receiving an enable signal (EN). The control circuit 106 may control the main switch 102 and the low-power switch 104 based on the enable signal. For example, the control circuit 106 may enable current flow through the main switch 102 and/or the low-power switch 104 based on a first state of EN, and the control circuit 106 may disable current flow through the main switch 102 and/or the low-power switch 104 based a second state of EN.

The main switch 102 includes a low-resistance switching device (e.g., an n-channel field effect transistor (NFET)) to conduct relatively large currents from the input power terminal to the output power terminal with low voltage drop (e.g., when a load circuit is drawing a larger current). The low-power switch 104 includes a higher resistance switching device (e.g., a smaller p-channel field effect transistor (PFET)) to conduct lower currents from the input power terminal to the output power terminal (e.g., when a load circuit is drawing a smaller current).

The control circuit 106 may sense the current flowing to the load by measuring the voltage across the main switch 102 and the low-power switch 104. If the voltage across the main switch 102 and the low-power switch 104 is less than a predetermined threshold voltage, then the control circuit 106 may provide the signal LPM in a first state to close the low-power switch 104 and configure the main switch 102 for operation in a low-power mode. If the voltage across the main switch 102 and the low-power switch 104 is greater than a predetermined threshold voltage, the control circuit 106 may provide LPM in a second state to open the low-power switch 104 and configure the main switch 102 for normal operation.

Controlling the main switch 102 may be more complex than controlling the low-power switch 104. For example, the low-power switch 104 may be closed by pulling the control terminal (e.g., gate) of a PFET to a voltage that is less than VBB while closing the main switch 102 may require pulling the control terminal (e.g., gate) of an NFET to a voltage greater than VBB. Accordingly, the control circuit 106 may include circuitry that generates a voltage for producing DRV that is greater than VBB. To reduce power consumption when operating in low-power mode, such circuitry may be disabled or powered-off. Circuitry of the control circuit 106 needed when not in low-power mode (normal mode), must be activated when transitioning from low-power mode to normal mode.

When operating in low-power mode, the main switch 102 may be configured to operate as a diode (e.g., to conduct current if the load current increases to a degree that results in a voltage drop across the main switch 102 greater than a threshold (e.g., a threshold voltage of an NFET of the main switch 102). Such configuration allows the main switch 102 to conduct current when the current flow to the load circuit increases while operating in low-power mode. However, if the current to the load circuit increases dramatically (e.g., a short circuit condition develops across the load circuit) while the main switch 102 is operating as a diode, the current flowing through the main switch 102 to the load may exceed the maximum operating current of the main switch 102 and damage the main switch 102.

To prevent damage to the main switch 102 when operating in low-power mode, the main switch 102 is configured to operate as diode only when the current to the load is stable or slowly increasing. Such operation may be referred to as “soft diode” operation. When the current to the load increases rapidly, the resistance of the main switch 102 increases to reduce the current flowing through the main switch 102, and provide time for the control circuit 106 to determine whether the main switch 102 should be opened. The control circuit 106 can detect a rapid change in the voltage across the main switch 102 (indicating a rapid increase in the current flowing to the load circuit). When the control circuit 106 detects a rapid change in voltage across the main switch 102, the control circuit 106 can set LPM to a state that disables low-power mode operation of the main switch 102 and the low-power switch 104 to protect the main switch 102 and the low-power switch 104 from damage.

When the voltage across the main switch 102 changes slowly, as when the current drawn by the load circuit increases slowly, the control circuit 106 detects the voltage drop, enables (e.g., powers on) the circuitry needed to generate DRV to close the main switch 102, and sets LPM to a state that disables low-power mode operation of the main switch 102 and the low-power switch 104. Thus, the high-side switch circuit 100 provides low-power mode operation when the current drawn by the load circuit is small, provides current flow through main switch 102 when operating in low-power mode and current drawn by the load circuit is changing slowly, and protects the main switch 102 when operating in low-power mode and current drawn by the load circuit is changing rapidly.

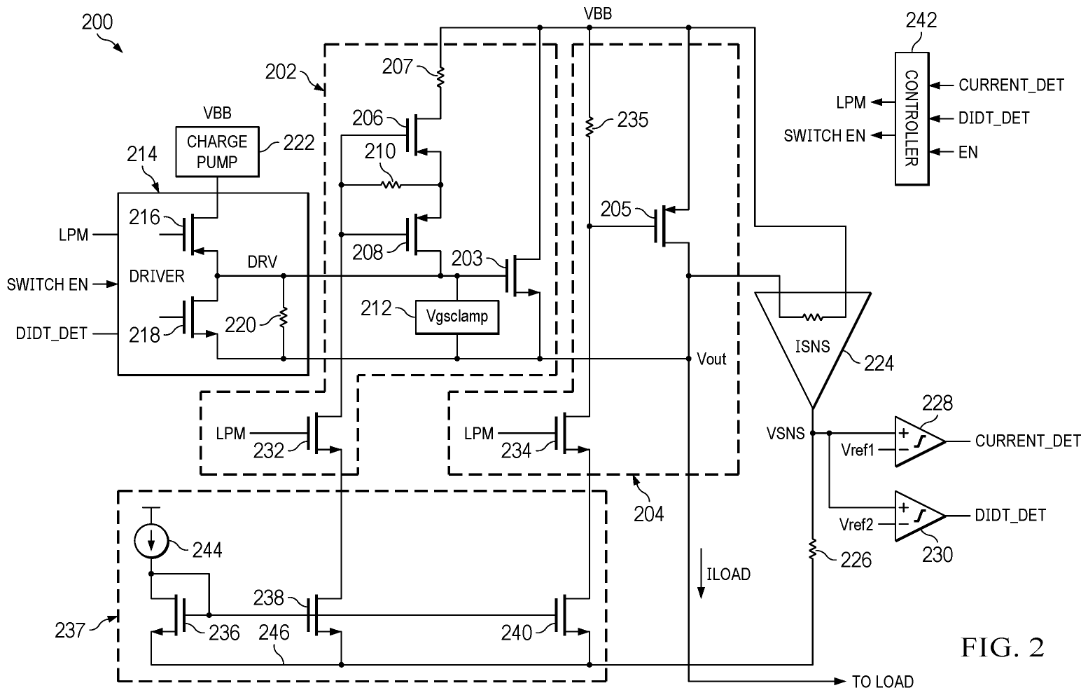

FIG. 2 is a schematic level diagram of an example high-side switch circuit 200 that includes “soft diode” operation. The high-side switch circuit 200 includes a main switch 202 and a low-power switch 204. The main switch 202 is an example of the main switch 102, and the low-power switch 204 is an example of the low-power switch 104. Other components of the high-side switch circuit 200 may be included in the control circuit 106. For example, the driver circuit 214, the charge pump circuit 222, the sense amplifier 224, the resistor 226, the comparator 228, the comparator 230, the current source 237, and the controller 242 may be components of an example of the control circuit 106.

The low-power switch 204 includes a transistor 205, a transistor 234, and a resistor 235. The transistor 205 may be a PFET, and the transistor 234 may be an NFET. The transistor 205 is coupled between the input power terminal and the output power terminal of the high-side switch circuit 200. A first current terminal (e.g., source) of the transistor 205 is coupled to the input power terminal of the high-side switch circuit 200, and a second current terminal (e.g., drain) of the transistor 205 is coupled to the output power terminal of the high-side switch circuit 200. The control terminal (e.g., gate) of the transistor 205 is coupled to the input power terminal of the high-side switch circuit 200 via the resistor 235. The transistor 234 is coupled between the control terminal of the transistor 205 and the current source 237. A first current terminal (e.g., drain) of the transistor 234 is coupled to the control terminal of the transistor 205. A second current terminal (e.g., source) of the transistor 234 is coupled to the current source 237. A control terminal (e.g., gate) of the transistor 234 is coupled to the controller 242 (a low-power mode terminal) for receipt of LPM.

When the high-side switch circuit 200 is operating in the low-power mode, the transistor 234 is turned on to pull-down (to a reference voltage, such as voltage less than VBB) the control terminal of the transistor 205, and turn on the transistor 205, allowing current to flow through the transistor 205 to the load circuit. When the high-side switch circuit 200 is operating in the normal mode, the transistor 234 is turned off, and the resistor 235 pulls up the control terminal of the transistor 205 to turn off the transistor 205.

The main switch 202 includes a transistor 203, a transistor 206, a resistor 207, a transistor 208, a resistor 210, a clamp circuit 212, and a transistor 232. The transistor 203 and the transistor 232 may be an NFETs. The transistor 206 and the transistor 208 may be PFETs. The transistor 203 is coupled between the input power terminal and the output power terminal of the high-side switch circuit 200. A first current terminal (e.g., drain) of the transistor 203 is coupled to the input power terminal and a second current terminal (e.g., source) of the transistor 203 is coupled to the output power terminal. A control terminal (e.g., gate) of the transistor 203 is coupled to a drive output of the driver circuit 214 for receipt of a drive signal (DRV). The clamp circuit 212 is coupled between the second current terminal and the control terminal of the transistor 203. The clamp circuit 212 limits the gate-source voltage of the transistor 203, and may include back-to-back diodes in some examples.

The transistor 206, the resistor 207, and the transistor 208 are coupled in series between the first current terminal of the transistor 203 and the control terminal of the transistor 203. The resistor 207 is coupled between a first current terminal (e.g., drain) of the transistor 206 and the input voltage terminal of the high-side switch circuit 200. A second current terminal (e.g., source) of the transistor 206 is coupled to a first current terminal (e.g., source) of the transistor 208. A second current terminal (e.g., drain) of the transistor 208 is coupled to the control terminal of the transistor 203. The control terminal of the transistor 206 is coupled to the control terminal of the transistor 208. The resistor 210 is coupled between the control terminal of the transistor 206 and the second current terminal of the transistor 206.

A first current terminal (e.g., drain) of the transistor 232 is coupled to the control terminals of the transistors 206 and 208. A second current terminal (e.g., source) of the transistor 232 is coupled to the current source 237. A control terminal (e.g., gate) of the transistor 232 is coupled to the controller 242 (a low-power mode terminal) for receipt of LPM. When the high-side switch circuit 200 is operating in the normal mode, LPM is at a logic low state, the transistor 232, the transistor 206, and the transistor 208 are turned off and the transistor 203 is not diode-connected. The signal DRV received from the driver circuit 214 drives the control terminal of the transistor 203 to a voltage that turns on the transistor 203 to enable current flow through the transistor 203. The voltage of the drive signal may be higher than the voltage at the input voltage terminal of the high-side switch circuit 200.

When the high-side switch circuit 200 is operating in the low-power mode, LPM is at a logic high state and turns on the transistor 232 to pull down the control terminals of the transistor 206 and the transistor 208. Turning on the transistor 206 and the transistor 208 diode-connects the transistor 203 through the resistor 207. The resistor 207 limits the current flowing from the input voltage terminal to the control terminal of the transistor 203 when the transistor 203 is diode-connected. The resistor 207 may have a resistance of about 100 kilo-ohms in some examples of the main switch 202. The resistor 207 may have a different resistance in some implementations of the main switch 202.

Because the transistor 203 is diode-connected through the substantial resistance of the resistor 207, the current allowed to flow to the control terminal of the transistor 203 through the resistor 207 is relatively small. When the high-side switch circuit 200 is operating in the low-power mode, and the current drawn by a load circuit increases suddenly, the voltage of the control terminal of the transistor 203 will tend to follow the voltage at the second control terminal of the transistor 203 (through the gate-to-source capacitor of the transistor 203). The gate-to-source voltage of the transistor 203 does not immediately increase as the source voltage of the transistor 203 drops with a sudden increase in load current. Instead, the voltage between the control terminal and the second current terminal of the transistor 203 increases slowly as a relatively small current flows through the resistor 207. Accordingly, a large current does not immediately flow through the transistor 203, and the transistor 203 is protected until the high-side switch circuit 200 can respond to the increased current by, for example, pulling the control terminal of the transistor 203 down to the voltage at the second current terminal of the transistor 203 (turning off the transistor 203).

The charge pump circuit 222 generates the drive voltage applied in the driver circuit 214 to produce DRV. The voltage provided by the charge pump circuit 222, to the driver circuit 214, may be greater than (e.g., five volts higher than) the voltage at the input voltage terminal of the high-side switch circuit 200. The driver circuit 214 includes a transistor 216 and a transistor 218. The transistor 216 may be a PFET and the transistor 218 may be an NFET. The transistor 216 switches the voltage received from the charge pump circuit 222 to produce a first state of DRV that turns on the transistor 203 based on LPM being a logic low. The transistor 218 pulls the DRV signal to voltage at the output voltage terminal of the high-side switch circuit 200 to turn off the transistor 203. When the high-side switch circuit 200 is operating in the low-power mode (e.g., LPM is a logic high), the charge pump circuit 222 and at least some circuitry of the driver circuit 214 may be disabled and/or powered-down to reduce power consumption.

The current source 237 sets the current flow through the transistor 232 and the transistor 234. The current source 237 includes a current source 244 and a current mirror circuit formed by the transistor 236, the transistor 238, and the transistor 240. The transistor 236 is diode-connected and coupled between the current source 244 and a reference terminal 246. The control terminal (e.g., gate) of the transistor 236 is coupled to the control terminal (e.g., gate) of the transistor 238 and the control terminal (e.g., gate) of the transistor 240. The transistor 238 is coupled between the transistor 232 and the reference terminal 246. The transistor 240 is coupled between the transistor 234 and the reference terminal 246.

The sense amplifier 224 senses the voltage drop across the transistor 203 and the transistor 205 (across the input voltage terminal and the output voltage terminal) to sense the current flowing to the load circuit. The sense amplifier 224 includes a first sense input coupled to the input voltage terminal and a second sense input coupled to the output voltage terminal. The sense amplifier 224 provides a sense signal (VSNS) at a sense output of the sense amplifier 224. VSNS represents (VSNS is a voltage that is proportional to) the current flowing through the transistor 203 and the transistor 205 to the load circuit. The resistor 226 is coupled between the sense output of the sense amplifier 224 and the reference terminal 246.

The comparator 228 compares VSNS to a first predetermined reference voltage (Vref1). The reference circuit providing Vref1 is not shown. Vref1 may define a threshold for low-power mode operation of the high-side switch circuit 200. The comparator 228 includes a comparator input coupled to the sense output, and a reference input coupled to the reference circuit. The comparator 228 provides, at a comparator output, an output signal (CURRNT_DET) that indicates whether VSNS exceeds Vref1. If VSNS exceeds Vref1, then the high-side switch circuit 200 operates in normal mode. In normal mode, the charge pump circuit 222, the driver circuit 214, and other circuits are enabled, and the DRV signal turns on the transistor 203. If VSNS does not exceed VRef1, then the high-side switch circuit 200 operates in low-power mode. In low-power mode, the charge pump circuit 222, the driver circuit 214, and other circuitry of the high-side switch circuit 200 are disabled or powered off to reduce the power consumed by the high-side switch circuit 200. In the low-power mode, the transistor 205 is turned-on, and the transistor 203 is diode-connected. In some examples of the high-side switch circuit 200, the Vref1 may be selected to set a 200 milliampere threshold for low-power mode operation.

The comparator 230 compares VSNS to a second predetermined reference voltage (Vref2). The reference circuit providing Vref2 is not shown. Vref2 may define a predetermined rate of change in the current flow to the load. When the high-side switch circuit 200 is operating in the low-power mode, and the load current increases rapidly, the control terminal of the transistor 203 is charged through the resistor 207, which produces a transient increase in the gate-to-drain voltage (V_{gd}) of the transistor 203 as:

$${V}_{g d} = {R}_{207} * {I}_{charge}$$

where:
R₂₀₇ is the resistance of the resistor 207 (e.g., 100 kilo-ohms); and
I_{charge} is the current flowing through the resistor 207 to charge the control terminal of the transistor 203.

The increase in V_{gd} causes a momentary increase the voltage across the transistor 203 (V_{ds}) as:

$${V}_{d s} = {V}_{g s} + {V}_{g d}$$

The comparator 230 detects a high rate of change in the load current by comparing VSNS to Vref2. The comparator 230 provides a signal DIDT_DET, at the output of the comparator 230, that indicates VSNS exceeds Vref2. The output of the comparator 230 is coupled to a high output slew detected input of the driver circuit 214. When DIDT_DET indicates that the load current increased rapidly, the driver circuit 214 may turn on the transistor 218 to turn off, and protect, the transistor 203 from damage due to overcurrent.

The controller 242 includes an input coupled to the output of the comparator 228 for receipt of CURRENT_DET, an input coupled to the output of the comparator 230 for receipt of DIDT_DET, and in input coupled to the enable input of the control circuit 106 for receipt of EN. The controller 242 includes an output for providing LPM to a low-power mode input of the driver circuit 214, the main switch 202, and the low-power switch 204. If EN is a logic low, then the controller 242 may provide LPM and SWITCH EN in a disable state (e.g., logic low) to turn off the transistor 203 and the transistor 205. If EN is a logic high, then the controller 242 may provide LPM based on CURRENT_DET and DIDT_DET. For example, if CURRENT_DET is a logic high, then the controller 242 may provide LPM in a disable state (e.g., logic low) to turn on the transistor 203 and turn off the transistor 205. The driver circuit 214 provides DRV to turn on the transistor 203 based on LPM being a logic low and SWITCH EN being a logic high. If CURRENT_DET is a logic low and DIDT_DET is a logic low, then the controller 242 may provide LPM in an enable state (e.g., logic high) to turn on the transistor 205 and diode-connect the transistor 203. If CURRENT_DET is a logic low and DIDT_DET is a logic high, the controller 242 may provide LPM as a logic low to turn off the transistor 205 and disable diode-connection of the transistor 203. The driver circuit 214 may set DRV to turn off the transistor 203 responsive to DIDT_DET being a logic high.

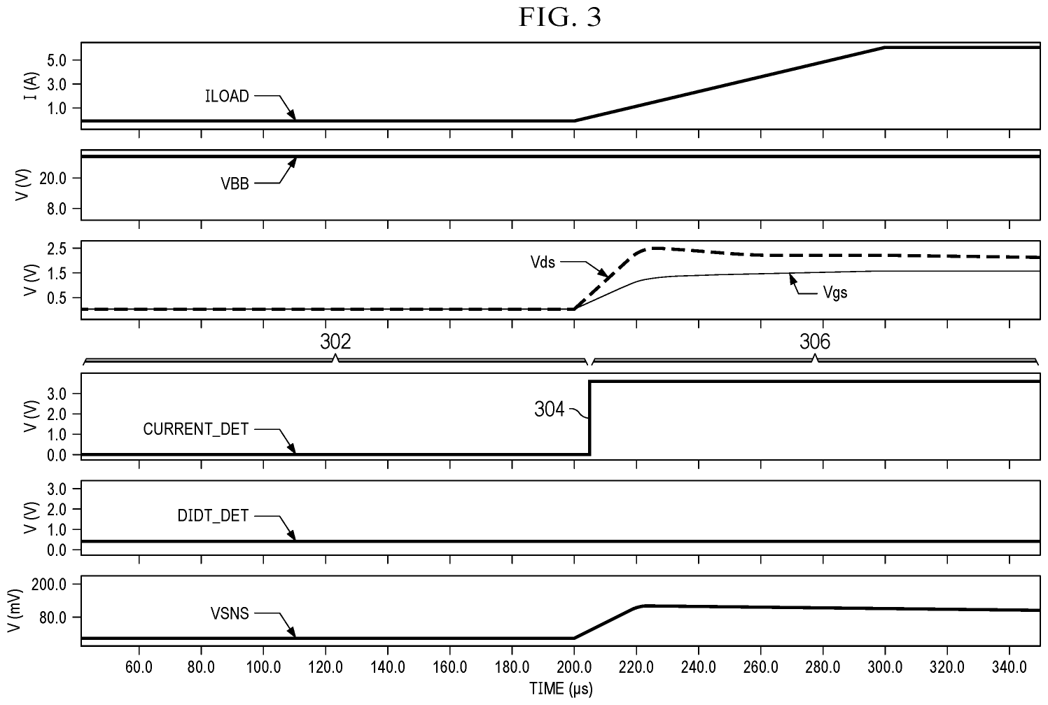

FIG. 3 is graph of example signals in the high-side switch circuit 200 with slowly increasing load current. FIG. 3 shows the load current (ILOAD), the input voltage (VBB), V_{ds} of the transistor 203, V_{gs} of the transistor 203, the signal CURRENT_DET, the signal DIDT_DET, and the signal VSNS. In the interval 302, ILOAD is less than the threshold current defined by VRef1, and the high-side switch circuit 200 is operating in the low-power mode. LPM is set to a logic high state, the transistor 203 is diode-connected and the transistor 205 is turned-on. At time 304, ILOAD exceeds the threshold current represented by VRef1. ILOAD is increasing slowly, and V_{ds} and V_{gs} increase slowly in turn. VSNS remains less than VRef2, and DIDT_DET remains a logic low. At time 304, LPM is set to a logic low state, the charge pump circuit 222 and the driver circuit 214 are enabled, the transistor 205 is turned off, and the diode-connection of the transistor 203 is disabled. The driver circuit 214 provides DRV to turn on the transistor 203. In the interval, 306, the high-side switch circuit 200 operates in the normal mode.

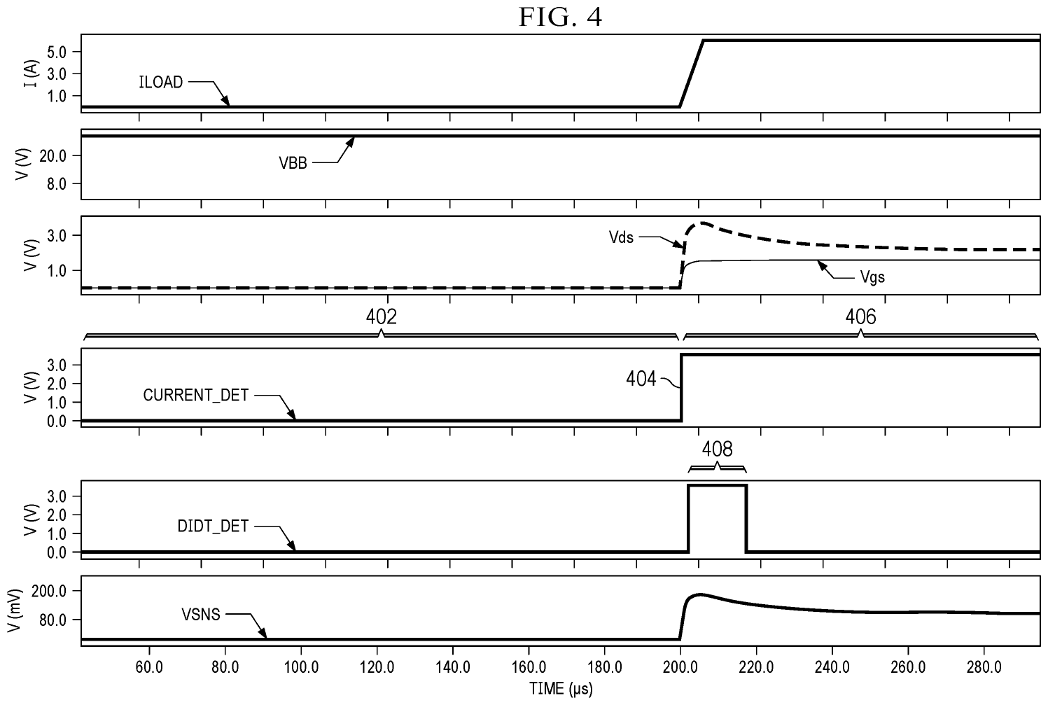

FIG. 4 is graph of example signals in the high-side switch circuit 200 with quickly increasing load current. FIG. 4 shows the load current (ILOAD), the input voltage (VBB), V_{ds} of the transistor 203, V_{gs} of the transistor 203, the signal CURRENT_DET, the signal DIDT_DET, and the signal VSNS. In the interval 402, ILOAD is less than the threshold current defined by VRef1, and the high-side switch circuit 200 is operating in the low-power mode. LPM is set to a logic high state, the transistor 203 is diode-connected and the transistor 205 is turned-on. At time 404, ILOAD exceeds the threshold current. ILOAD is increasing rapidly, and V_{ds} increases rapidly with a transient overshoot resulting from the current flow through the resistor 207. VSNS is proportional to V_{ds} and exceeds VRef2 for an interval 408, as reflected in DIDT_DET. Responsive to DIDT_DET, the driver circuit 214 turns off the transistor 203, and the transistor 203 is protected from overcurrent damage. Responsive to CURRENT_DET, the high-side switch circuit 200 sets LPM to a logic low state to turn off the transistor 205 and disable diode-connection of the transistor 203. With LPM set to a logic low, the charge pump circuit 222, driver circuit 214, and other circuitry active in normal mode may be activated (e.g., powered on) to turn on the transistor 203.

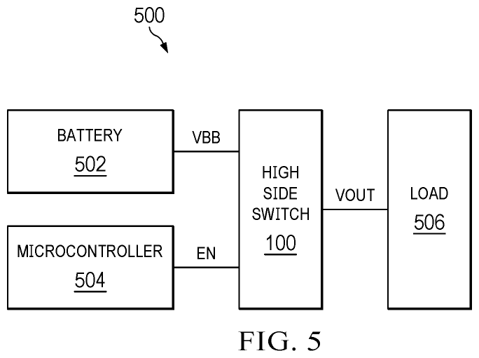

FIG. 5 is a block diagram of an example system 500 that includes the high-side switch circuit 100 or the high-side switch circuit 200. The system 500 includes a battery 502 (or other power source), a microcontroller 504, the high-side switch circuit 100, and a load circuit 506. A battery voltage output of the battery 502 is coupled to the input voltage terminal of the high-side switch circuit 100. An output voltage terminal of the high-side switch circuit 100 is coupled to a power input of the load circuit 506. An enable output of the microcontroller 504 is coupled to the enable input of the high-side switch circuit 100. The microcontroller 504 provides the enable signal (EN) to the high-side switch circuit 100 to control the state of the high-side switch circuit 100 (to control current flow through the high-side switch circuit 100 to the load circuit 506. As described herein, soft diode operation of the high-side switch circuit 100 protects the main switch 102 from damage caused by excessive current flow to the load circuit 506 or a short circuit across the load circuit 506.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a first transistor coupled between a switch voltage input and a switch voltage output, the first transistor having a first control terminal;
a second transistor coupled between the switch voltage input and the first control terminal, the second transistor having a second control terminal (gate) coupled to a low-power mode terminal; and
a resistor coupled in series with the second transistor between the switch voltage input and the first control terminal.

2. The circuit of claim 1, further comprising:
a driver circuit including:
a low-power mode input;
a high output slew detected input;
a drive output; and
a third transistor coupled between the drive output and a reference terminal, the third transistor including a third control terminal coupled to the high output slew detected input;
wherein the drive output is coupled to the first control terminal.

3. The circuit of claim 2, further comprising a charge pump circuit coupled to a power terminal of the driver circuit.

4. The circuit of claim 2, further comprising:
a sense amplifier having a first sense input, a second sense input and a sense output, in which:
the first sense input is coupled to the switch voltage input; and
the second sense input is coupled to the switch voltage output; and
a comparator having a first comparator input, a first reference input, and a first comparator output, in which:
the first comparator input is coupled to the sense output;
the first reference input is coupled to a first reference terminal; and
the first comparator output is coupled to a controller.

5. The circuit of claim 4, wherein:
the comparator is a first comparator; and
the circuit includes:
a second comparator having a second comparator input, a second reference input, and a second comparator output, in which:
the second comparator input is coupled to the sense output;
the first reference input is coupled to a second reference terminal; and
the second comparator output is coupled to the high output slew detected input.

6. The circuit of claim 1, further comprising:
a third transistor coupled between the switch voltage input and the switch voltage output, the third transistor having a third control terminal coupled to a low-power mode terminal.

7. The circuit of claim 6, further comprising:
a fourth transistor coupled between the second control terminal and a reference terminal, the fourth transistor having a fourth control terminal coupled to the low-power mode terminal; and
a fifth transistor coupled between the third control terminal and the reference terminal, the fifth transistor having a fifth control terminal coupled to the low-power mode terminal.

8. A circuit comprising:
a first transistor having a first current terminal, a second current terminal, and a control terminal, in which:
the first current terminal is coupled to a switch voltage input;
the second current terminal is coupled to a switch voltage output;
the first transistor is configured to operate as a diode based on a low-power mode signal;
a second transistor coupled between the first current terminal and the control terminal, the second transistor configured to diode-connect the first transistor based on the low-power mode signal; and
a resistor coupled in series with the second transistor between the control terminal and the first current terminal, the resistor configured to limit current flow from the switch voltage input to the control terminal.

9. The circuit of claim 8, further comprising:
a driver circuit including a drive output coupled to the control terminal, the driver circuit configured to:
turn on the first transistor based on the low-power mode signal; and
turn off the first transistor responsive to the first transistor being diode-connected and based on a slew detect signal.

10. The circuit of claim 9, further comprising a charge pump circuit coupled to the driver circuit, the charge pump circuit configured to provide a drive voltage to the driver circuit for driving the first transistor.

11. The circuit of claim 9, further comprising:
a sense amplifier including:
a first sense input is coupled to the switch voltage input;
a second sense input is coupled to the switch voltage output; and
a sense output;
in which the sense amplifier is configured to provide, at the sense output, a sense signal representing a current flow from the switch voltage input to the switch voltage output;
a comparator configured to:
compare the sense signal to a reference voltage; and
provide a current detect signal indicating that the current flowing from the switch voltage input to the switch voltage output exceeds a threshold.

12. The circuit of claim 11, wherein:
the comparator is a first comparator;
the reference voltage is a first reference voltage; and
the circuit includes:
a second comparator configured to:
compare the sense signal to a second reference voltage; and
provide the slew detect signal indicating that the current flowing from the switch voltage input to the switch voltage output is increasing at greater than a predetermined rate.

13. The circuit of claim 12, wherein the driver circuit is configured to turn off the first transistor responsive to the slew detect signal.

14. The circuit of claim 8, further comprising:
a third transistor coupled between the switch voltage input and the switch voltage output, the third transistor configured to conduct current from the switch voltage input to the switch voltage output based on the low-power mode signal.

15. A circuit comprising:
a battery having a battery voltage output;
a load circuit having a load voltage input;
a controller having a switch enable output; and
a high-side switch circuit having a switch voltage input, a switch voltage output, and a switch control input, in which:
the switch voltage input is coupled to the battery voltage output;
the switch voltage output is coupled to the load voltage input;
the switch control input is coupled to the switch enable output;
the high-side switch circuit includes:
a first transistor having a first current terminal, a second current terminal, and a control terminal, in which:
the first current terminal is coupled to the switch voltage input;
the second current terminal is coupled to the switch voltage output;
the first transistor is configured to operate as a diode based on a low-power mode signal;
a second transistor coupled between the first current terminal and the control terminal, the second transistor configured to diode-connect the first transistor based on the low-power mode signal; and
a resistor coupled between the second transistor and the switch voltage input, the resistor configured to limit current flow from the switch voltage input to the control terminal.

16. The circuit of claim 15, further comprising a third transistor coupled between the switch voltage input and the switch voltage input, the third transistor configured to conduct current from the switch voltage input to switch voltage input based on the low-power mode signal.

17. The circuit of claim 15, further comprising:
a driver circuit including a drive output coupled to the control terminal, the driver circuit configured to:
turn on the first transistor based on the low-power mode signal; and
turn off the first transistor responsive to the first transistor being diode-connected and based on a slew detect signal.

18. The circuit of claim 17, further comprising a charge pump circuit coupled to the driver circuit, the charge pump circuit configured to provide a drive voltage to the driver circuit for driving the first transistor.

19. The circuit of claim 17, further comprising:
a sense amplifier including:
a first sense input is coupled to the switch voltage input;
a second sense input is coupled to the switch voltage output; and
a sense output;
in which the sense amplifier is configured to provide, at the sense output, a sense signal representing a current flow from the switch voltage input to the switch voltage output;
a comparator configured to:
compare the sense signal to a reference voltage; and
provide a current detect signal indicating that the current flowing from the switch voltage input to the switch voltage output exceeds a threshold.

20. The circuit of claim 19, wherein:
the comparator is a first comparator;
the reference voltage is a first reference voltage; and
the high-side switch circuit includes:
a second comparator configured to:
compare the sense signal to a second reference voltage; and
provide the slew detect signal indicating that the current flowing from the switch voltage input to the switch voltage output is increasing at greater than a predetermined rate; and
the driver circuit is configured to turn off the first transistor responsive to the slew detect signal.
